(19) United States
(12) Patent Application Publication
(10) Pub. No.: US 2012/0248380 A1
(43) Pub. Date: Oct. 4, 2012

(54) NANOWIRE INK SOLUTION AND METHOD OF FORMING THE INK SOLUTION

(75) Inventors: Taeyoon LEE, Seoul (KR); Jungmok SEO, Gyeonggi-do (KR); Ja Hoon KOO, Seoul (KR); Seul Ah LEE, Seoul (KR)

(73) Assignee: Industry-Academic Cooperation Foundation, Yonsei University, Seoul (KR)

(21) Appl. No.: 13/353,882

(22) Filed: Jan. 19, 2012

(30) Foreign Application Priority Data
Mar. 30, 2011 (KR) 10-2011-0028908

(51) Int. Cl. C09D 11/00; H05K 1/09; H01B 1/00; B82Y 40/00; B82Y 30/00

(52) U.S. Cl. 252/500; 174/257; 106/31.13; 977/762; 977/840

(57) ABSTRACT

Provided is a method of manufacturing a nanowire and a nanowire device using a nanowire ink solution. The nanowire ink solution includes nanowires having two or more sizes.

### CROSS-REFERENCE TO RELATED APPLICATIONS

This U.S. non-provisional patent application claims priority under 35 U.S.C. §119 of Korean Patent Application No. 10-2011-0028908, filed on Mar. 30, 2011, the entire contents of which are hereby incorporated by reference.

### BACKGROUND OF THE INVENTION

Exemplary embodiments of the inventive concepts herein relate to a nanoparticie ink solution and a method of manufacturing the same.

Existing silicon-based transistors reach the limit in performance. Thus, a material having a new concept and structure that is called a nano material as a next generation device which can overcome the limitations of the existing device performance is being proposed, and also researches with respect to the nano material are being actively executed.

A nanowire of the nano material has a wire shape with a nano-sized diameter. Thus, the nanowire may be applied to various electronic device fields. Specifically, a nanowire network device is being significantly spotlighted because it can be applied to various industrial fields, e.g., transistor or sensor manufacturing fields. In recent, a lot of research is being executed worldwide.

The nanowire has superior electrical and optical properties, large selectivity in case where a chemical material and an energy band structure are distinguished from each other, superior crystalline quality, and superior mobility of charge carrier. Thus, the nanowire is being utilized in various nano devices such as sensors and transistors.

In addition, since the nano material can be shifted onto a desired substrate at a low temperature after the nano material is grown, the nano material can be free from the many limitations occurring due to a high process temperature in the existing silicon-based transistors. If a flexible substrate formed of a material such as polymer is processed at a high temperature, the polymer substrate may be deformed. Thus, there is a limitation in application of the existing silicon-based process method. However, since a substrate can be processed at a low temperature when the method in which the nano material is shifted onto the substrate is performed, there is an advantageous that the nano material can be utilized in various industrial fields in which the flexible substrate is used,

To obtain a desired nanowire network or pattern using nanowire ink, comprehensions of the nanowire ink and technologies that can control the movement of the nanowire in a solution are necessary.

### SUMMARY OF THE INVENTION

Example embodiments of the inventive concepts provide a nanowire ink solution which can control movement of a nanowire and a method of manufacturing the same.

Example embodiments of the inventive concepts also provide a method of manufacturing a high density nanowire using a nanowire ink solution.

Example embodiments of the inventive concepts also provide an electronic device including a nanowire and a method of manufacturing the same.

Example embodiments of the inventive concepts also provide a nanoparticle ink solution and a method of manufacturing the same.

Embodiments of the inventive concepts provide nanowire ink solutions including nanowires which have two or more normal distributions as a diameter distribution.

In some embodiments, the nanowires having a normal distribution with a relatively large average diameter may have a relatively low volume percentage with respect to the whole nanowire ink solution when compared to the nanowires having a normal distribution with a relatively small average diameter.

In other embodiments, the nanowires may include a first nanowire group having an average diameter of about 100˜300 nm and a second nanowire group having an average diameter of about 400˜700 nm. The first nanowire group may have about 1%˜15% by volume of the whole nanowire ink solution, and the second nanowire group may have about 0.1%˜5% by volume of the whole nanowire ink solution.

In other embodiments of the inventive concepts, methods of forming a nanowire comprising coating the nanowire ink solution nano on a substrate, the nanowire ink solution including nanowires having two or more normal distributions as a diameter distribution.

In still other embodiments of the inventive concepts, an electronic device comprises a nanowire manufactured by coating a nanowire ink solution including the nanowires with two or more normal distributions as a diameter distribution onto a substrate.

In even other embodiments of the inventive concepts, a method of manufacturing a nanowire ink solution comprises: preparing nanowires having two or more normal distributions as a diameter distribution; and dispersing the nanowires into a solution.

In some embodiments, the preparing of the nanowires having two or more normal distributions as the diameter distribution may comprise: preparing a first nanowire group having an average diameter of about 100˜300 nm at about 1˜15% by volume of the whole nanowire ink solution; and preparing a second nanowire group having an average diameter of about 400˜700 nm at about 0.1˜5% by volume of the whole nanowire ink solution,

In yet other embodiments of the inventive concepts, a nanowire ink solution comprises: a first nanowire group; and a second nanowire group having an average diameter greater than an average diameter of the first nanowire group and a volume % less than a volume % of the first nanowire group.

In some embodiments, the substrate may have a groove having a width gradually decreasing downward, and the first and second nanowire groups are disposed within the groove.

In other embodiments, the second nanowire group may be disposed on an edge of the groove, and the first nanowire group may he disposed on the second nanowire group.

In still other embodiments, the substrate may include a flexible substrate, a transparent substrate, or a glass substrate.

In further embodiments of the inventive concepts, a nanowire ink solution comprises nanowires having two or more sizes.

In still further embodiments of the inventive concepts, a nanoparticle ink solution comprises nano materials with two or more normal distributions as a size distribution.

### BRIEF DESCRIPTION OF THE DRAWINGS

The accompanying drawings are included to provide a further understanding of the exemplary embodiments of the inventive concepts, and are incorporated in and constitute a part of this specification. The drawings illustrate exemplary embodiments of the inventive concepts and, together with the description, serve to explain principles of inventive concepts. In the drawings:

FIG. 1 is a schematic view of a normal distribution curve;

FIG. 2 is a schematic view of an equivalent normal distribution curve;

FIG. 3 is a schematic view illustrating a distribution of diameters of nanowires in a nanowire ink solution according to an embodiment of the inventive concepts;

FIG. 4 is a schematic view illustrating a method of manufacturing a nanowire ink solution according to an embodiment of the inventive concepts;

FIG. 5 is a schematic view illustrating a diameter distribution of a nanowire ink solution according to an embodiment of the inventive concepts;

FIG. 6 is a view for explaining a method of forming a nanowire according to an embodiment of the inventive concepts;

FIG. 7 is a photography illustrating a nanowire formed using a nanowire ink solution of FIG. 6; and

FIG. 8 is a photography illustrating a nanowire formed using a nanowire ink solution which expresses one normal distribution as a diameter distribution (has a single size).

### DETAILED DESCRIPTION OF PREFERRED EMBODIMENTS

Advantages and features of exemplary embodiments of the inventive concepts, and implementation methods thereof will be clarified through following embodiments described with reference to the accompanying drawings. Also, these embodiments are provided so that this disclosure will be thorough and complete, and will fully convey the scope of the inventive concepts to those skilled in the art. Since the inventive concepts may have diverse modified embodiments, embodiments are illustrated in the drawings and are described in the detailed description of the invention. However, this does not limit the inventive concepts within specific embodiments and it should be understood that the inventive concepts covers all the modifications, equivalents, and replacements within the idea and technical scope of the inventive concepts. In the following description, the technical terms are used only for explaining a specific exemplary embodiment while not limiting the present disclosure.

The terms of a singular form may include plural forms unless referred to the contrary. The meaning of ‘include’ or ‘comprise’ specifies a property, a region, a fixed number, a step, a process, an element and/or a component but does not exclude other properties, regions, fixed numbers, steps, processes, elements and/or components.

Unless terms used in the present disclosure are defined differently, the terms may be construed as meaning known to those skilled in the art. Terms such as terms that are generally used and have been in dictionaries should be construed as having meanings matched with contextual meanings in the art. In this description, unless defined clearly, terms are not ideally, excessively construed as formal meanings.

Embodiments of the inventive concepts will be described below in more detail with reference to the accompanying drawings.

Embodiments of the inventive concepts provide a nano ink solution including a nano material or nanoparticle and a method of manufacturing the same. The nano material may refer to a nanowire, a nano tube, a nano rod, a nano needle, a nano powder, and/or a combination thereof.

Hereinafter, a nano ink solution and a method of manufacturing the same, a nanowire using a nanowire ink solution and a method of forming an electronic device, and a nanowire and electronic device which are manufactured by the foregoing methods will be described. Following embodiments may be applied to other nano materials such as a nano tube, a nano rod, a nano needle, and a nano powder as well as the nanowire.

Nanowire Ink Solution

A nanowire ink solution according to an embodiment of the inventive concepts includes nanowires having two or more sizes. In the specification, that nanowires or nanoparticles have two or more sizes means that the nanowires or nanoparticles have at least one of following characteristics,

1. A distribution of diameters of the nanowires or nanoparticles has two or more normal distributions having an average diameter different from each other

2. A distribution of diameters of the nanowires or nanoparticles has two or more diameter peaks different from each other;

3. A distribution of diameters of the nanowires or nanoparticles has two or more normal distributions having curve shapes different from each other.

In the specification, it should be understood that a normal distribution represents a generally normal distribution as well as ‘equivalent normal distributions’ similar to the generally normal distribution.

That is, in the specification, the normal distribution means a generally normal distribution and/or equivalent normal distribution. In the specification, it should be understood that the equivalent normal distribution includes various types of distributions having curve shape similar to that of the normal distribution, such as a distribution in which a normal distribution does not have vertical symmetry with respect to an average, a distribution in which an average is moved toward a left or right side, and/or a distribution in which an average does not accord with a peak.

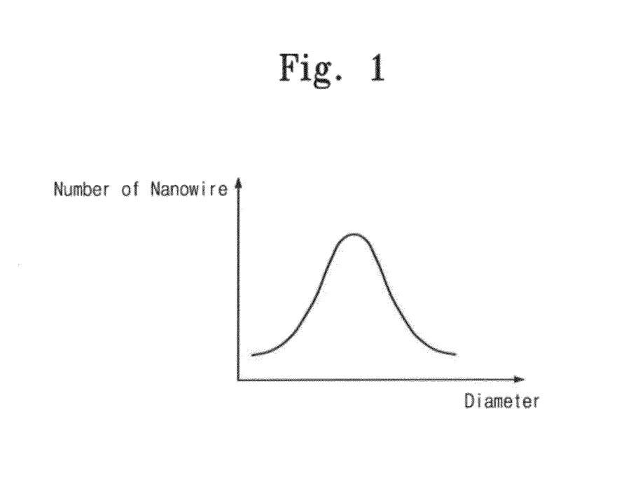

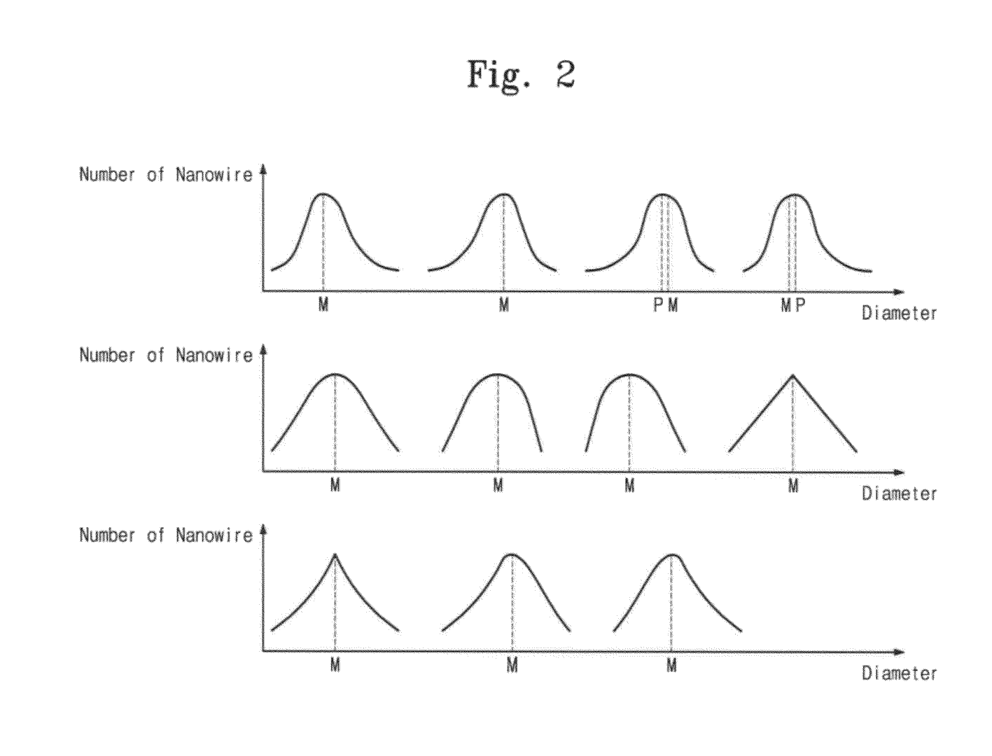

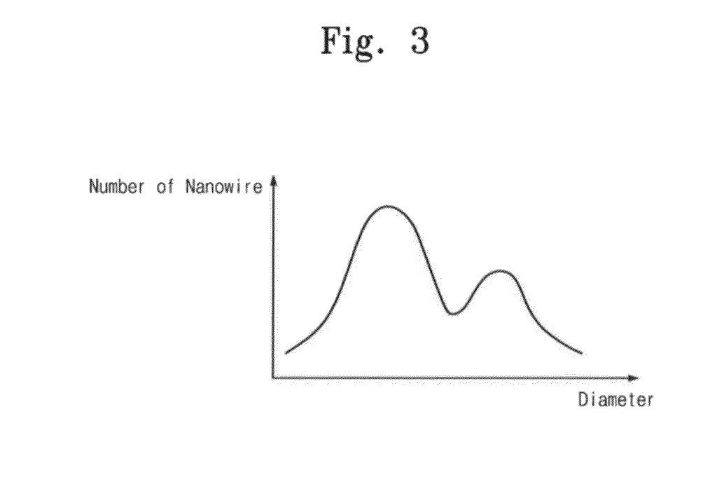

FIG. 1 illustrates a generally normal distribution curve. FIG. 2 illustrates various equivalent normal distribution curves similar to the normal distribution curve. FIG. 3 illustrates two normal distribution curves having average diameters different from each other. The equivalent normal distribution defined in the specification is not limited to FIG. 2. For example, the equivalent normal distribution may have various forms. Also, the two normal distributions having average diameters different from each other are not limited to FIG. 3. For example, the two normal distributions may have various forms.

The nanowire may include a wire having a nano-sized diameter or a structure having a wire shape, such as a metallic (Ni, Pt, Au, etc) nanowire, a semiconductor (Si, InP, GaN, ZnO, etc) nanowire, and an insulation (SiO₂, TiO₂), etc) nanowire. For example, the semiconductor nanowire may be formed of a single material such as a silicon nanowire. The semiconductor nanowire may have a heterostructure in which semiconductor materials different from each such as InP are coupled to each other. Also, the metallic nanowire and the insulation nanowire may have a heterostructure.

According to an embodiment of the inventive concepts, a nanowire having high density is formed on a substrate using a nanowire ink solution having two or more sizes. The nanowire having the high density may be effectively formed on a desired position by an entropy force.

The nanowire ink solution includes nanowires having two or more sizes. In order to increase an entropy of the whole system, nanowires with difference size have a tendency that nanowires having a relatively low volume fraction may be aligned, and nanowires having relatively high volume fraction are freely moved. Thus, the nanowires may be well aligned or disposed on the substrate.

For example, according to an embodiment of the inventive concepts, the nanowire ink solution includes a nanowire group having a relative large average diameter in a normal distribution with a relatively low volume fraction and a nanowire group having a relatively small average diameter in a normal distribution with a relatively high volume fraction. Thus, the nanowire group having the relatively low volume fraction and large diameter may be aligned first on the substrate, and then, the nanowire group having the relatively high volume fraction and small diameter may be aligned to form the nanowire having the high density.

The nanowire ink solution according to an embodiment of the inventive concepts may include a first nanowire group having a first normal distribution and a second nanowire group having a second normal distribution. For example, the first nanowire group may have an average diameter of about 100˜300 nanometers. Also, the first nanowire group may have about 1%˜15% by volume of the whole nanowire ink solution. For example, the second nanowire group may have an average diameter of about 400˜700 nanometers. Also, the first nanowire group may have about 0.5%˜5% by volume of the whole nanowire ink solution.

In case where the nanowire ink solution having two or more sizes is used, the nanowires may be more easily disposed on desired positions when compared to the nanowires having a single size.

In an embodiment of the inventive concepts, the first nanowire group may be different from the second nanowire group. For example, the first nanowire group may be a semiconductor nanowire group, and the second nanowire group may be a metallic nanowire group. Also, the first nanowire group may be a silicon nanowire group, and the second nanowire group may be a ZnO nanowire group.

Manufacture of Nanowire Ink Solution

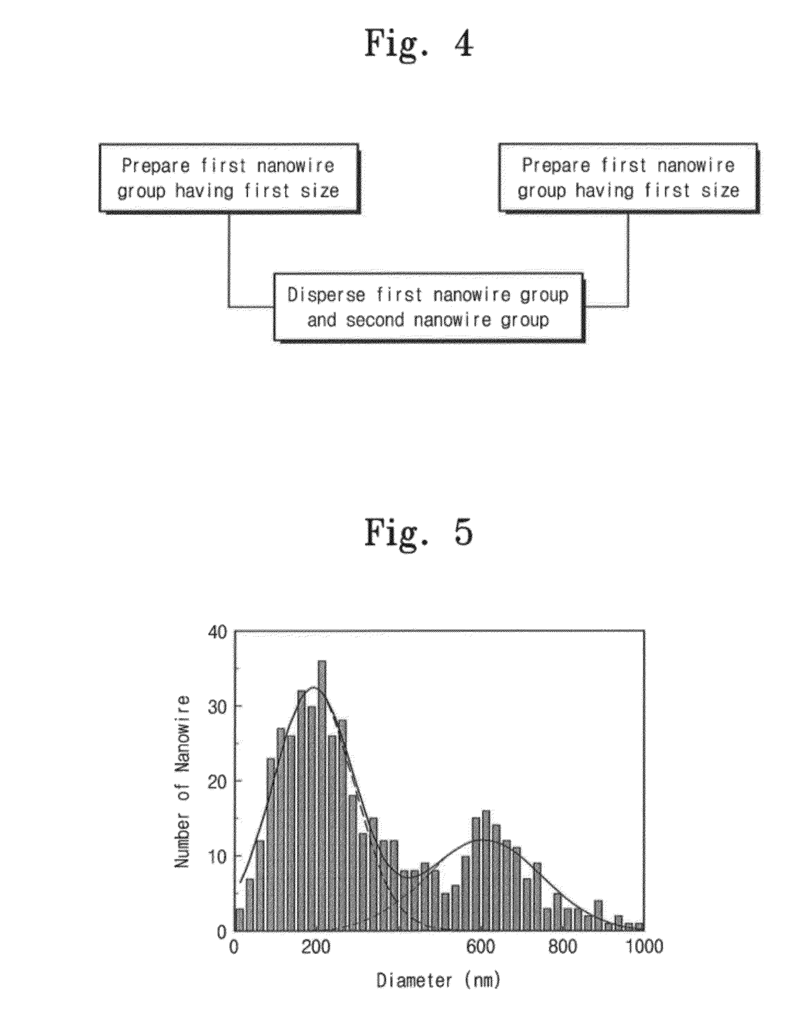

FIG. 4 is a schematic view illustrating a method of manufacturing a nanowire ink solution according to the inventive concepts.

A process of manufacturing a nanowire ink solution according to an embodiment of the inventive concepts may include a process of preparing nanowires having two or more sizes. A first nanowire group having a first size is prepared. Also, a second nanowire group having a second size is prepared. The first nanowire group and the second nanowire group may express a first normal distribution having a first average diameter and a second normal distribution having a second average diameter, respectively.

The nanowires may be prepared through the widely known nanowire manufacturing process. For example, in case where the nanowires are grown using a seed or catalyst, when the nanowires are grown using seeds or catalysts which have diameters different from each other, the nanowires having two or more sizes may be prepared. For example, when nanowires having a diameter of about 200 nm are formed, seeds or catalysts having a diameter of about 200 nm may be used. Here, a distribution of the diameters of the formed nanowires may express a normal distribution having an average of about 200 nm. For example, when nanowires having a diameter of about 400 nm are formed, seeds or catalysts having a diameter of about 400 nm may be used. Here, a distribution of the diameters of the formed nanowires may express a normal distribution having an average of about 400 nm.

Next, first and second nanowire groups may be dispersed into an adequate solution to manufacture a nanowire ink having two or more sizes. The solution in which the nanowires are dispersed may have the same polarity as the nanowires. For example, when the first and second nanowire groups have hydrophilicity, a hydrophilic solution may be used. Also, when the first and second nanowire groups have hydrophobicity, a hydrophobic solution may be used.

For example, the first and second nanowire groups may be put into a solution such as isopropyl alcohol, and then sonication may be performed on the mixture to disperse the first and second nanowire groups, thereby manufacturing the nanowire ink solution.

The nanowire group having a relatively large diameter (e.g., the second nanowire group) may be contained in the nanowire ink solution at a low % by volume when compared to the nanowire group having a relatively small diameter (e.g., the first nanowire group). For example, the second nanowire group having the relatively large diameter may be contained at about 0.1%˜5% by volume of the whole nanowire ink solution. The first nanowire group having the relatively small diameter may be contained at about 1%˜15% by volume of the whole nanowire ink solution.

FIG. 5 is a schematic view illustrating a diameter distribution of a nanowire ink solution according to an embodiment of the inventive concepts. Referring to FIG. 5, it is seen that a nanowire ink solution expresses two normal distributions having averages different from each other.

Substrate on which Nanowire is Formed

According to an embodiment of the inventive concepts, when a nanowire ink solution has hydrophilicity, an area of a substrate on which a nanowire is to be formed may have the hydrophilicity.

Also, an entropy of a solution containing nanowires having various sizes may be further increased when the substrate on which the nanowire is to be formed has physically patterned features. Thus, the nanowires may be more easily aligned or patterned. For example, the substrate on which the nanowire is to be formed may have a groove or trench. The groove may have a shape with a gradually narrow width downward from a top surface of the substrate. For example, the groove may have various shapes such as a wedge shape, a V shape, and a reverse pyramid shape in section.

Also, the substrate on which the nanowire is to be formed may include a transparent substrate or a glass substrate.

Nanowire Formation

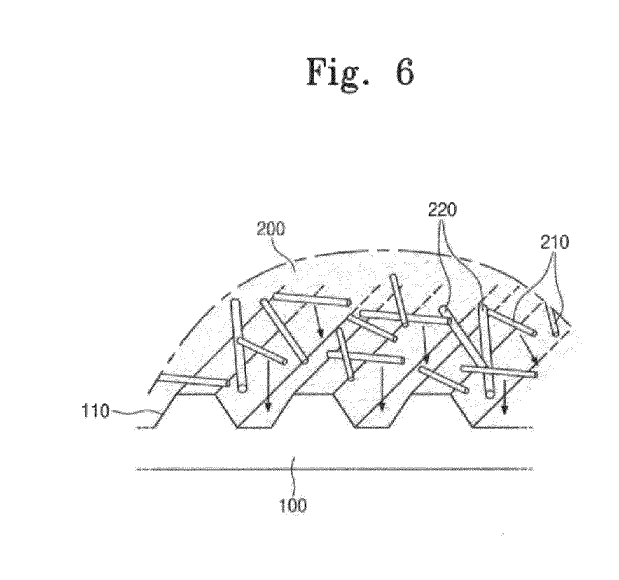

FIG. 6 is a view for explaining a method of forming a nanowire according to an embodiment of the inventive concepts. Referring to FIG. 6, to align nanowires on a substrate, a substrate 100 having a three-dimensional structure, for example a groove 110 in a top surface is prepared. Although a groove 110 defined in the top surface of the substrate 100 has a trench shape extending in one direction of a trapezoid section, the inventive concepts is not limited thereto. For example, the groove 110 may have a V shape in section. Also, to form a desired nanowire or nanowire network pattern, the groove may have various desired shapes and sizes in bottom. As shown in FIG. 5, both sidewalls of the groove 110 may be inclined so that the more a depth of the groove 110 is deep, the more a width of the groove 110 is narrow. The groove 110 may be provided in plurality in the top surface of the substrate 100. The plurality of grooves 110 may extend in parallel. For example, the groove 110 may be formed by performing a wet or dry etching process on a silicon substrate. In a state where an etching area having a stripe shape as an etch mask is opened on the silicon substrate, the silicon substrate may be etched using an etchant, e.g., KOH to form the groove 110 as shown in FIG. 5.

After the substrate 100 is prepared, a nanowire ink solution 60 in which first and second nanowire groups 210 and 220 are dispersed is sprayed onto the three-dimensional structure (top surface) of the substrate 100. Then, the nanowire ink solution 200 sprayed onto the three-dimensional structure of the substrate 100 may be sufficiently dried to form nanowires well aligned at high density in the groove 110.

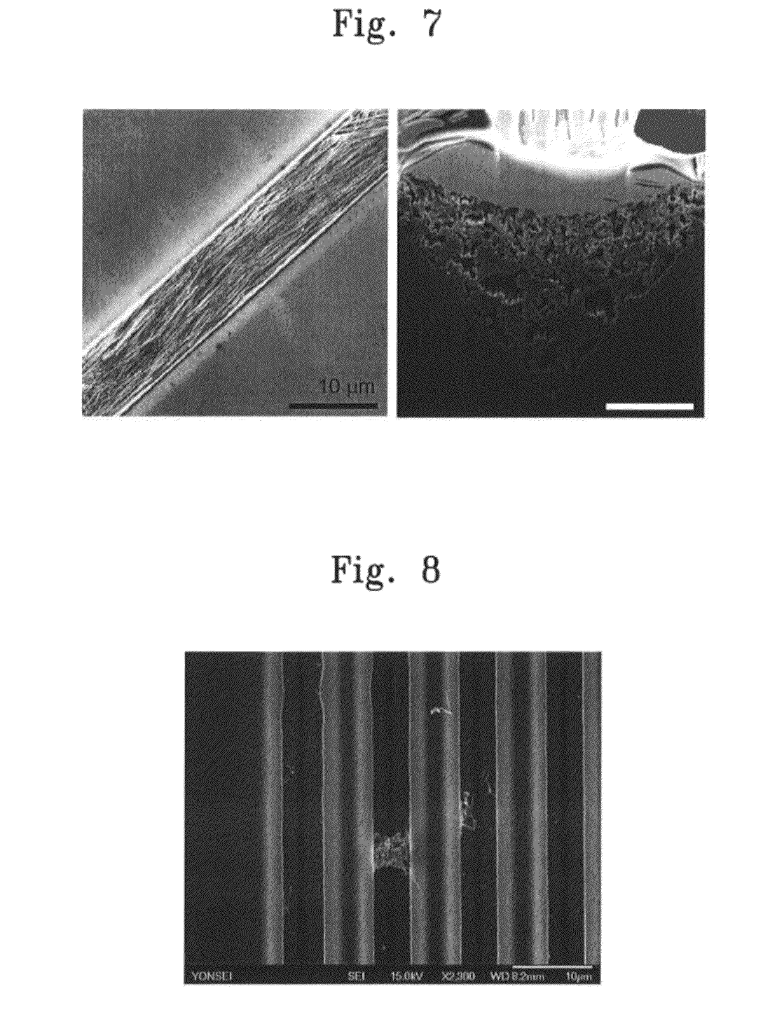

FIG. 7 is a photography illustrating a nanowire formed using a nanowire ink solution of FIG. 6. As shown in FIG. 7, it is seen that the nanowire having high density is formed.

FIG. 8 is a photography illustrating a nanowire formed using a nanowire ink solution which expresses one normal distribution as a diameter distribution (has a single size). When a nanowire ink solution having one size is used, it may be difficult to easily align the nanowires. Also, the aligned nanowires may have low density. In addition, it is clearly seen that it is be difficult to form desired pattern when compared to that of FIG. 7. As shown in FIG. 8, the nanowires have a tendency to get together. Also, the nanowires have low density, and it is confirmed that it is difficult to form desired patterns.

Although the process of manufacturing the nanowire is described in the above-described embodiments, the embodiments according to the inventive concepts may be applied to a process of manufacturing a thin film using the nanowire ink solution including a nano-sized material (nano material or nanoparticle) without departing from the spirit and scope of the invention. For example, the nanoparticle may include an insulation nanoparticle, a conductive nanoparticle, a semiconductor nanoparticle, a quantum dot or a combination thereof For example, the embodiments according to the inventive concepts may be applied to a conductive nanoparticle ink solution such as a metal for forming a conductive thin film.

The nanoparticle ink solution according to an embodiment of the inventive concepts includes the nano materials having average sizes (e.g., average diameters) different from each other and two or more normal distributions. The nano material may include the nano tube, the nano rod, the nano needle, and the nano powder.

According to an embodiment of the inventive concepts, a fluid flow within the nanowire ink solution may be adjusted to control the movement of the desired nanowire, thereby manufacturing the nanowire having high density.

According to an embodiment of the inventive concepts, a fluid flow within the nanowire ink solution may be adjusted to control the movement of the desired nanowire, thereby manufacturing a nano material-based thin film having high density.

The nanowire ink solution and/or nano material ink solution according to an embodiment of the inventive concepts may be applied to the manufacture of various electronic devices such as a thin film transistor (TFT), a liquid crystal display (LCD), an organic light emitting device (OLED), a solar cell, a nanowire network device, and a flexible device.

The above-disclosed subject matter is to be considered illustrative, and not restrictive, and the appended claims are intended to cover all such modifications, enhancements, and other embodiments, which fall within the true spirit and scope of the inventive concepts. Thus, to the maximum extent allowed by law, the scope of the inventive concepts is to be determined by the broadest permissible interpretation of the following claims and their equivalents, and shall not be restricted or limited by the foregoing detailed description.

What is claimed is:

1. A nanowire ink solution comprising nanowires having two or more normal distributions in a diameter.

2. The nanowire ink solution according to claim 1, wherein the nanowires having a normal distribution with a relatively large average diameter have a relatively low % by volume with respect to the whole nanowire ink solution when compared to the nanowires having a normal distribution with a relatively small average diameter.

3. The nanowire ink solution according to claim 1, wherein the nanowires comprise a first nanowire group having an average diameter of about 100˜300 nm and a second nanowire group having an average diameter of about 400˜700 nm.

4. The nanowire ink solution according to claim 3, wherein the first nanowire group has about 1˜15% by volume of the whole nanowire ink solution, and the second nanowire group has about 0.1˜5% by volume of the whole n.anowire ink solution.

5. A method of forming a nanowire comprising coating the nanowire ink solution according to claim 4 onto a substrate.

6. An electronic device comprising a nanowire manufactured by coating the nanowire ink solution according to claim 4 onto a substrate.

7. A method of manufacturing a nanowire ink solution, the method comprising:
preparing nanowires having two or more normal distributions in a diameter; and
dispersing the nanowires into a solution.

8. The method according to claim 7, wherein the preparing nanowires having two or more normal distributions in a diameter comprises:
preparing a first nanowire group having an average diameter of about 100˜300 nm at about 1˜15% by volume of the whole nanowire ink solution; and
preparing a second nanowire group having an average diameter of about 400˜700 nm at about 0.1˜5% by volume of the whole nanowire ink solution.

9. A nanowire ink solution comprising:
a first nanowire group; and
a second nanowire group having an average diameter greater than an average diameter of the first nanowire group and a volume % less than a volume % of the first nanowire group.

10. The nanowire ink solution according to claim 9, wherein the first nanowire group has a normal distribution with an average diameter of about 100˜300 nm, and the second nanowire group has a normal distribution with an average diameter of about 400˜700 nm.

11. The nanowire ink solution according to claim 9, wherein the first nanowire group has about 1%˜15% by volume of the whole nanowire ink solution, and the second nanowire group has about 0.1˜5% by volume of the whole nanowire ink solution.

12. A method of forming a nanowire comprising coating the nanowire ink solution according to claim 11 onto a substrate.

13. An electronic device comprising a nanowire manufactured by coating the nanowire ink solution according to claim 11 onto a substrate.

14. An electronic device comprising a nanowire disposed on a substrate, the nanowire comprises:
a first nanowire group; and
a second nanowire group having an average diameter relatively greater than an average diameter of the first nanowire group and a volume % relatively less than a volume % of the first nanowire group.

15. The electronic device of claim 14, wherein the first nanowire group has an average diameter of about 100˜300 nm, and the second nanowire group has an average diameter of about 400˜700 nm.

16. The electronic device according to claim 14, wherein the substrate has a groove having a width gradually decreasing downward, and the first and second nanowire groups are disposed within the groove.

17. The electronic device of claim 17, wherein the second nanowire group is disposed on an edge of the groove, and the first nanowire group is disposed on the second nanowire group.

18. The electronic device of claim 16, wherein the substrate comprises a flexible substrate, a transparent substrate, or a glass substrate.

19. A nanowire ink solution comprising nanowires having two or more sizes.

20. A nanoparticle ink solution comprising nano materials having two or more normal distributions in a diameter.
